(19) United States
(12) Patent Application Publication
(10) Pub. No.: US 2025/0372314 A1
(43) Pub. Date: Dec. 4, 2025

(54) CAPACITOR, ELECTRICAL CIRCUIT, CIRCUIT BOARD, DEVICE, AND DIELECTRIC MATERIAL FOR CAPACITOR

(71) Applicant: Panasonic Intellectual Property Management Co., Ltd., Osaka (JP)

(72) Inventors: TAKAYA UENO, Osaka (JP); TOMOYASU YOKOYAMA, Osaka (JP); KOSEI OHURA, Osaka (JP)

(21) Appl. No.: 19/299,213

(22) Filed: Aug. 13, 2025

Related U.S. Application Data
(63) Continuation of application No. PCT/JP2024/006151, filed on Feb. 21, 2024.

(30) Foreign Application Priority Data
Mar. 3, 2023 (JP) 2023-033161

(51) Int. Cl. H01G 9/07; H05K 1/18

(52) U.S. Cl. CPC H01G 9/07; H05K 1/18; H05K 2201/10015

(57) ABSTRACT

The present disclosure provides a capacitor that is advantageous in terms of a capacitance and a dielectric breakdown field. According to the present disclosure, a capacitor comprises a first electrode, a second electrode, and a dielectric material. The dielectric material is disposed between the first electrode and the second electrode. The dielectric material comprises a predetermined composite oxide. The composite oxide is composed of O, at least one selected from the group consisting of K, Rb, and Cs, at least one selected from the group consisting of Si, Ge, and Sn, and at least one selected from the group consisting of Mo and W.

### BACKGROUND

### 1. Technical Field

The present disclosure relates to a capacitor and a dielectric material for the capacitor and also relates to an electrical circuit, a circuit board, and a device.

### 2. Description of the Related Art

In the related art, dielectric materials containing a composite oxide are known.

For example, PTL 1 describes an integrated circuit including a non-ferroelectric high-dielectric-constant insulator. This insulator includes a thin film of a metal oxide. One of the described metal oxides is a pyrochlore-type oxide having a general formula of A₂B₂O₇. A represents an A-site atom selected from a metal group consisting of Ba, Bi, Sr, Pb, Ca, K, Na, and La. B represents a B-site atom selected from a metal group consisting of Ti, Zr, Ta, Hf, Mo, W, and Nb.

NPL 1 describes improvement of a BaTa₂O₆ thin film in order to use the film as a gate insulator of a thin film transistor (TFT). NPL2 describes variations in a dielectric constant of the BaTa₂O₆ thin film with respect to oxygen partial pressures.

NPL 2 describes a measurement result of a dielectric constant of a BaNb₂O₆ thin film.

### CITATION LIST

### Patent Literature

PTL 1: PTL 1

### Non-Patent Literature

NPL 1: Son Bui Tien et al., “Improvement of BaTa2O6 Thin Films for TFT Gate Insulator Applications”, The 66th JSAP Spring Meeting, 2019
NPL 2: D. W. KIM et al., “Crystallographic orientation dependence of the dielectric constant in polymorphic BaNb2O6 thin films deposited laser ablation”, Phys. A 79, 677-680 (2004)

### SUMMARY

The technologies described in the above-mentioned literatures have room for further study in terms of a capacitance and a dielectric breakdown field of a capacitor that uses a dielectric material containing a composite oxide.

One non-limiting and exemplary embodiment provides a capacitor that uses a dielectric material containing a composite oxide and which is advantageous in terms of a capacitance and a dielectric breakdown field.

In one general aspect, the techniques disclosed here feature a capacitor comprising a first electrode, a second electrode, and a dielectric material disposed between the first electrode and the second electrode, the dielectric material comprising a composite oxide, wherein the composite oxide is composed of O, at least one selected from the group consisting of K, Rb, and Cs, at least one selected from the group consisting of Si, Ge, and Sn, and at least one selected from the group consisting of Mo and W.

The present disclosure provides a capacitor that uses a dielectric material containing a composite oxide and which is advantageous in terms of a capacitance and a dielectric breakdown field. Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a cross-sectional view illustrating an exemplary capacitor of the present disclosure;

FIG. 2 is a cross-sectional view illustrating another exemplary capacitor of the present disclosure;

FIG. 3 is a cross-sectional view illustrating yet another exemplary capacitor of the present disclosure;

FIG. 4 is a cross-sectional view illustrating still another exemplary capacitor of the present disclosure;

FIG. 5 is a schematic diagram illustrating an exemplary electrical circuit of the present disclosure;

FIG. 6 is a schematic diagram illustrating an exemplary circuit board of the present disclosure;

FIG. 7 is a schematic diagram illustrating an exemplary device of the present disclosure;

FIG. 8 is a graph showing an X-ray diffraction (XRD) pattern of a composite oxide of a Reference Example;

FIG. 9 is a diagram illustrating a stable structure of CsTi_{0.5}W_{1.5}O₆;

FIG. 10A is a diagram illustrating a stable structure of CsSi_{0.5}W_{1.5}O₆;

FIG. 10B is a diagram illustrating a stable structure of CsGe_{0.5}W_{1.5}O₆;

FIG. 10C is a diagram illustrating a stable structure of CsSn_{0.5}W_{1.5}O₆;

FIG. 10D is a diagram illustrating a stable structure of KSi_{0.5}W_{1.5}O₆;

FIG. 10E is a diagram illustrating a stable structure of KGe_{0.5}W_{1.5}O₆;

FIG. 10F is a diagram illustrating a stable structure of KSn_{0.5}W_{1.5}O₆;

FIG. 10G is a diagram illustrating a stable structure of RbSi_{0.5}W_{1.5}O₆;

FIG. 10H is a diagram illustrating a stable structure of RbGe_{0.5}W_{1.5}O₆; and

FIG. 10I is a diagram illustrating a stable structure of RbSn_{0.5}W_{1.5}O₆.

### DETAILED DESCRIPTIONS

### Underlying Knowledge Forming Basis of the Present Disclosure

In the related art, regarding capacitors including a dielectric material containing a composite oxide, studies have been conducted on the combination of elements that are included in the composite oxide. In PTL 1, for example, the A-site atom in a pyrochlore-type oxide having a general formula of A₂B₂O₇ is selected from a metal group consisting of Ba, Bi, Sr, Pb, Ca, K, Na, and La. In addition, the B-site atom in the pyrochlore-type oxide is selected from a metal group consisting of Ti, Zr, Ta, Hf, Mo, W, and Nb. The pyrochlore-type oxide disclosed in PTL 1 is a composite oxide represented by (BaₓSr₁₋ₓ)₂(Ta_{y}Nb₁₋ₓ)₂O₇, where the conditions of 0≤x≤1.0 and 0≤y≤1.0 are satisfied. The metal oxide materials described in PTL 1 have a relatively high dielectric constant and are used in integrated circuits.

Regarding the characteristics of capacitors, a high dielectric constant of the dielectric material is important from the standpoint of the capacitance of the capacitors, and a dielectric breakdown field is also important; the dielectric breakdown field is an upper limit of an electric field that can be applied to the dielectric material.

Accordingly, the present inventors diligently conducted studies to develop a capacitor that is advantageous in terms of a high capacitance and a high dielectric breakdown field. As a result, it was newly discovered that in instances where a dielectric material containing a composite oxide formed of a combination of elements that is not described in the above-mentioned literatures is used in a capacitor, the capacitor is likely to have a high capacitance and may have a high dielectric breakdown field. Based on this new finding, the present inventors invented the capacitor of the present disclosure.

### Embodiments of the Present Disclosure

Embodiments of the present disclosure will be described below with reference to the drawings.

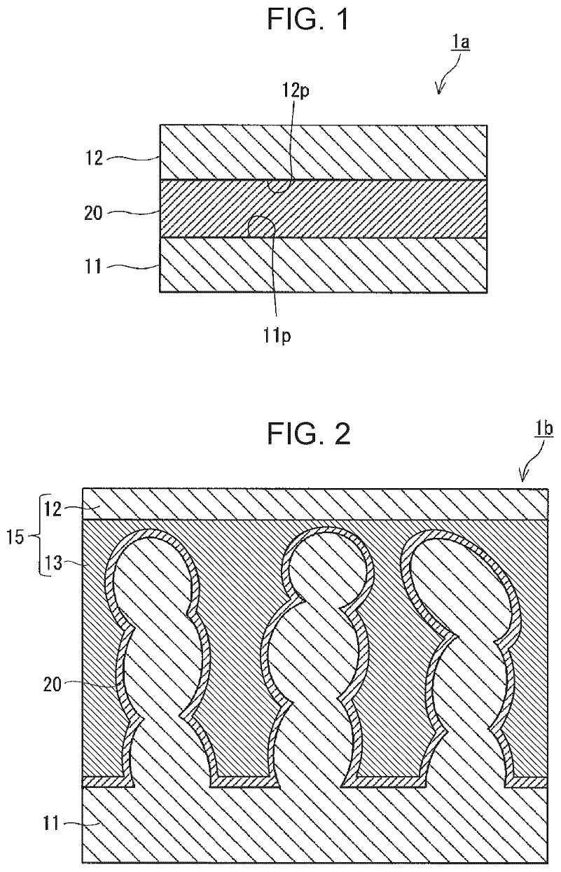

FIG. 1 is a cross-sectional view illustrating an exemplary capacitor of the present disclosure. As illustrated in FIG. 1, a capacitor 1a includes a first electrode 11, a second electrode 12, and a dielectric material 20. The dielectric material 20 is disposed between the first electrode 11 and the second electrode 12. The dielectric material 20 contains a predetermined composite oxide. The composite oxide is composed of O, at least one selected from the group consisting of K, Rb, and Cs, at least one selected from the group consisting of Si, Ge, and Sn, and at least one selected from the group consisting of Mo and W. Since the dielectric material 20 contains such a composite oxide, the dielectric material 20 is likely to have a high relative dielectric constant, which makes it likely that the capacitor la has a high capacitance. In addition, the dielectric material 20 is likely to have a high dielectric breakdown field. Consequently, the capacitor la is likely to have an increased energy density. The composite oxide may contain trace amounts of impurities. The trace amounts of impurities may be elemental species other than the elemental species mentioned above. The trace amounts of impurities may be present, for example, in an amount less than or equal to 5 mass % based on the total mass of the composite oxide.

As an example, the composite oxide comprises one of K, Rb, and Cs. In this case, the dielectric material 20 is more likely to have a high relative dielectric constant and a high dielectric breakdown field. The composite oxide may contain two or more selected from the group consisting of K, Rb, and Cs. In this instance, a ratio of the number of atoms of one of the K, Rb, and Cs that is present in the largest amount, in terms of number of atoms, to the total number of atoms of the K, Rb, and Cs is, for example, greater than or equal to 70%. The ratio may be greater than or equal to 80%, greater than or equal to 90%, greater than or equal to 95%, or greater than or equal to 99%.

The composite oxide may contain one of Cs and K. In this instance, the dielectric material 20 is more likely to have a high relative dielectric constant and a high dielectric breakdown field.

As an example, the composite oxide comprises one of Si, Ge, and Sn. In this case, the dielectric material 20 is more likely to have a high relative dielectric constant and a high dielectric breakdown field. The composite oxide may contain two or more selected from the group consisting of Si, Ge, and Sn. In this instance, the ratio of the number of atoms of one of the Si, Ge, and Sn that is present in the largest amount, in terms of number of atoms, to the total number of atoms of the Si, Ge, and Sn is, for example, greater than or equal to 70%. The ratio may be greater than or equal to 80%, greater than or equal to 90%, greater than or equal to 95%, or greater than or equal to 99%.

As an example, the composite oxide comprises one of Mo and W. In this case, the dielectric material 20 is more likely to have a high relative dielectric constant and a high dielectric breakdown field. The composite oxide may contain both Mo and W. In this instance, the ratio of the number of atoms of either of the Mo and W that is present in a larger amount, in terms of number of atoms, to the total number of atoms of the Mo and W is, for example, greater than or equal to 70%. The ratio may be greater than or equal to 80%, greater than or equal to 90%, greater than or equal to 95%, or greater than or equal to 99%.

The composite oxide may contain one of K, Rb, and Cs, one of Si, Ge, and Sn, and one of Mo and W. In this case, the dielectric material 20 is more likely to have a high relative dielectric constant and a high dielectric breakdown field.

The composition of the composite oxide is not limited to any particular composition. For example, the composite oxide has a composition represented by A_{α}B_{β}C_{γ}O_{δ}. In this composition, A is at least one selected from the group consisting of K,

Rb, and Cs, B is at least one selected from the group consisting of Si, Ge, and Sn, and C is at least one selected from the group consisting of Mo and W. This composition satisfies conditions of 0.9≤α≤1.1, 0.25≤β≤1, 1≤γ≤2, and 5.5≤δ≤6.5. In the case where the composite oxide has such a composition, the dielectric material 20 is more likely to have a high relative dielectric constant and a high dielectric breakdown field.

The composition may satisfy a condition of α=1. The composition may satisfy a condition of 0.3≤β≤0.9, 0.3≤β≤0.8, 0.3≤β≤0.7, 0.3≤β≤0.6, 0.4≤β≤0.6, or β=0.5. The composition may satisfy a condition of y=1.5. The composition may satisfy a condition of δ=6.

The crystal structure of the composite oxide is not limited to a particular crystal structure. For example, the composite oxide has a pyrochlore-type crystal structure. In this case, the dielectric material 20 is more likely to have a high relative dielectric constant and a high dielectric breakdown field.

The entirety of the dielectric material 20 may be formed of the composite oxide, or a portion of the dielectric material 20 may be formed of the composite oxide. In the dielectric material 20, the composite oxide may be in the form of a continuous phase or a dispersed phase.

The relative dielectric constant of the dielectric material 20 is not limited to any particular value. The relative dielectric constant of the dielectric material 20 may be greater than or equal to 55, greater than or equal to 60, greater than or equal to 70, greater than or equal to 80, or greater than or equal to 100. The relative dielectric constant of the dielectric material 20 is less than or equal to 10,000. In other words, the relative dielectric constant of the dielectric material 20 is, for example, greater than or equal to 55 and less than or equal to 10,000.

The dielectric breakdown field of the dielectric material 20 is not limited to any particular value. A dielectric breakdown field at −273° C. of the dielectric material 20 is, for example, greater than or equal to 10 V/nm and may be greater than or equal to 13 V/nm or greater than or equal to 16 V/nm. The dielectric breakdown field at −273° C. of the dielectric material 20 is, for example, less than or equal to 20 V/nm. In other words, the dielectric breakdown field at −273° C. of the dielectric material 20 is greater than or equal to 10 V/nm and less than or equal to 20 V/nm.

The literature mentioned below describes an energy above hull as an index for evaluating a stability and a reactivity of a compound, where the energy above hull is an energy deviation from a thermodynamic convex hull. From the literature, it is seen that the closer the energy above hull is to 0, the higher the stability of the compound; for example, when the energy above hull is less than or equal to 0.1 eV/atom, the possibility of the existence of the compound is high, and the stability of the compound is relatively high (see FIG. 4 of the literature). Regarding compounds having the following compositions, their energies above hull, calculated by first-principles calculation, are shown in Table 1 as examples.

Koki Muraoka & Miura Akira, “Development of ceramics for electronics, and evaluation methods and applications thereof, Chapter IX, Paragraph I, Thermodynamic stability and reactivity of materials according to computational chemistry and informatics”, Technical Information Institute Co., Ltd., 2020 (URL: https://eprints.lib.hokudai.ac.jp/dspace/bitstream/2115/79152/3/Final_20200804%E F%BC%BFHUSCUP_4.pdf)

TABLE 1

| | Energy Above |
|---|---|
| Composition | Hull [eV/atom] |
| CsGe_{0.5}W_{1.5}O₆ | 0 |
| CsSi_{0.5}W_{1.5}O₆ | 0 |
| CsSn_{0.5}W_{1.5}O₆ | 0 |
| KGe_{0.5}Mo_{1.5}O₆ | 0.029 |
| KGe_{0.5}W_{1.5}O₆ | 0 |
| RbGe_{0.5}W_{1.5}O₆ | 0 |
| RbSi_{0.5}W_{1.5}O₆ | 0 |
| RbSn_{0.5}W_{1.5}O₆ | 0.008 |

From Table 1, it is seen that these composite oxides can stably exist.

Processes for producing the composite oxide are not limited to any particular process. The composite oxide may be produced with reference to the process described in the literature mentioned below. An example is as follows. A stoichiometric mixture of a nitric acid salt of at least one selected from the group consisting of K, Rb, and Cs, an oxide of at least one selected from the group consisting of Si, Ge, and Sn, and an oxide of at least one selected from the group consisting of Mo and W is prepared. The mixture is sintered in air at a predetermined temperature for a predetermined length of time to provide a powder. The resulting powder is processed in a solvent, such as cyclohexane, in a ball mill. Subsequently, the powder is compacted into a pallet and heat-treated in air at a predetermined temperature for a predetermined length of time. In this manner, the composite oxide can be produced.

Gordon J. et al., “Diffuse scattering in the cesium pyrochlore CsTi_{0.5}W_{1.5}O₆”, Materials Research Bulletin, Volume 43, Issue 4, 1 Apr. 2008, Pages 787-795, [DOI: https://doi.org/10.1016/j.materresbull.2007.12.017]

The crystal structure of the composite oxide can be determined by performing Rietveld analysis on diffraction data which can be obtained, for example, by powder X-ray diffraction measurement or powder neutron diffraction measurement. The powder neutron diffraction measurement is performed, for example, as follows. A high-resolution powder diffractometer of the High Flux Australian Reactor (HIFAR) of Australian Nuclear Science and Technology Organisation (ANSTO) is used. A sample of the composite oxide is placed in a thin-walled vanadium can. Subsequently, the measurement is performed with neutrons having a wavelength of 1.337 Å over an angular range of 10°≤2θ≤150° with a step size of 0.05°. The powder X-ray diffraction measurement is performed, for example, as follows. A Debye-Scherrer diffractometer is used. The sample of the composite oxide is placed in a thin-walled quartz capillary. Subsequently, the measurement is performed with X-rays having a wavelength of 0.80088 Å over an angular range of 5°≤2θ≤85° with a step size of 0.01°.

In the capacitor 1a, the dielectric material 20 is in the form of, for example, a film, as illustrated in FIG. 1. The method for placing the dielectric material 20 is not limited to a particular process. For example, the dielectric material 20 may be formed by spin coating, ink jetting, die coating, roll coating, bar coating, Langmuir-Blodgett technique, dip coating, or spray coating. In this case, the dielectric material 20 is more likely to have a high relative dielectric constant and a high dielectric breakdown field. The dielectric material 20 may be formed by sputtering, anodizing, vacuum vapor deposition, pulsed laser deposition (PLD), atomic layer deposition (ALD), or chemical vapor deposition (CVD).

As illustrated in FIG. 1, the dielectric material 20 is disposed, for example, between the first electrode 11 and the second electrode 12 in a thickness direction of the dielectric material 20. The second electrode 12 covers, for example, at least a portion of the dielectric material 20.

Each of the materials of the first electrode 11 and the second electrode 12 is not limited to a particular material. For example, the first electrode 11 and the second electrode 12 each contain a metal. The first electrode 11 contains, for example, a valve metal. Examples of the valve metal include Al, Ta, Nb, and Bi. For example, the first electrode 11 contains, as the valve metal, at least one selected from the group consisting of Al, Ta, Nb, and Bi. The first electrode 11 may contain a precious metal, such as gold or platinum. The first electrode 11 may contain Ni. The first electrode 11 may contain a metal element of Group 13, 14, or 15.

The second electrode 12 may, for example, contain a valve metal, such as Al, Ta, Nb, or Bi, contain a precious metal, such as gold, silver, or platinum. The second electrode 12 may contain Ni. The second electrode 12 may contain a metal element of Group 13, 14, or 15. The second electrode 12 contains, for example, at least one selected from the group consisting of Al, Ta, Nb, Bi, gold, silver, platinum, and Ni.

As illustrated in FIG. 1, the first electrode 11 has a principal surface 11p. One of the principal surfaces of the dielectric material 20 is, for example, in contact with the principal surface 11p. The second electrode 12 has a principal surface 12p, which is, for example, parallel to the principal surface 11p. The other principal surface of the dielectric material 20 is, for example, in contact with the principal surface 12p.

FIG. 2 is a cross-sectional view illustrating another exemplary capacitor of the present disclosure. A capacitor 1b, illustrated in FIG. 2, has a configuration similar to that of the capacitor 1a, except for portions that are particularly described. Constituent elements of the capacitor 1b that are the same as or correspond to the constituent elements of the capacitor 1a are assigned the same reference numerals, and details thereof will not be described. The descriptions of the capacitor 1a apply to the capacitor 1b as long as there is no technical inconsistency. The same applies to a capacitor 1c and a capacitor 1d, which will be described below.

As illustrated in FIG. 2, the capacitor 1b is an electrolytic capacitor. In the capacitor 1b, at least a portion of the first electrode 11 is porous. With this configuration, the first electrode 11 is likely to have a large surface area, which makes it more likely that the capacitor 1b has a high capacitance. Such a porous structure can be formed by any of the processes including, for example, etching of metal foil and powder sintering processes.

As illustrated in FIG. 2, the film of the dielectric material 20 is disposed, for example, on the surface of the porous portions of the first electrode 11. Examples of processes for forming the dielectric material 20 that can be employed include spin coating, ink jetting, die coating, roll coating, bar coating, Langmuir-Blodgett technique, dip coating, and spray coating. The dielectric material 20 may be formed, for example, by sputtering, anodizing, vacuum vapor deposition, PLD, ALD, or CVD.

The first electrode 11 contains, for example, a valve metal, such as Al, Ta, Nb, Zr, Hf, and Bi. The second electrode 12 may contain, for example, a solidified product of a silver-containing paste; a carbon material, such as graphite; or both the solidified product of the silver-containing paste and the carbon material, such as graphite.

In the capacitor 1b, an electrolyte 13 is disposed between the first electrode 11 and the second electrode 12. Specifically, the electrolyte 13 is disposed between the dielectric material 20 and the second electrode 12. In the capacitor 1b, for example, the second electrode 12 and the electrolyte 13 constitute a cathode 15. In the capacitor 1b, the electrolyte 13 is disposed, for example, to fill a space around the porous portions of the first electrode 11.

The electrolyte 13 includes, for example, at least one selected from the group consisting of an electrolyte solution and a conductive polymer. Examples of the conductive polymers include polypyrrole, polythiophene, polyaniline, and derivatives thereof. The electrolyte 13 may be a manganese compound, such as manganese oxide. The electrolyte 13 may contain a solid electrolyte.

The electrolyte 13 containing a conductive polymer can be formed by polymerizing a raw material monomer on the dielectric material 20 by performing chemical polymerization, electrolytic polymerization, or both chemical polymerization and electrolytic polymerization. The electrolyte 13 containing a conductive polymer can also be formed by disposing a solution or dispersion of a conductive polymer onto the dielectric material 20.

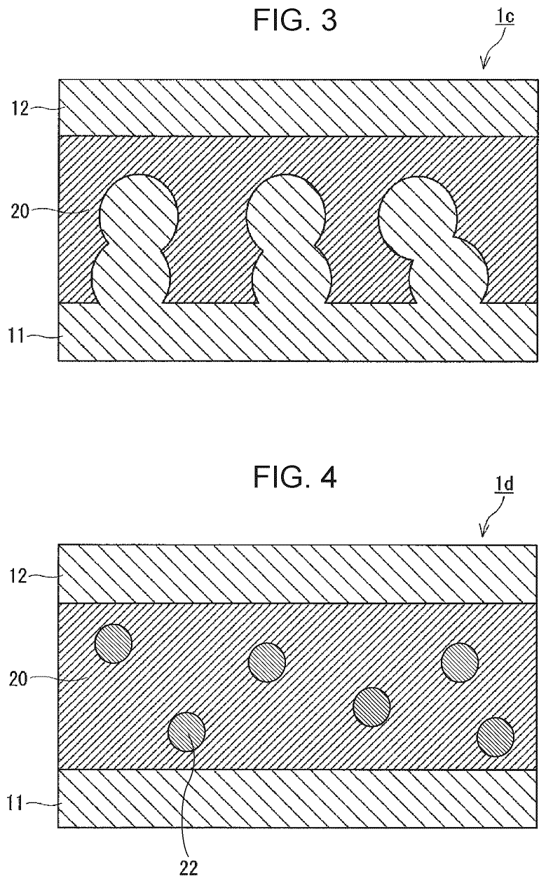

FIG. 3 is a cross-sectional view illustrating yet another exemplary capacitor of the present disclosure. In a capacitor 1c, illustrated in FIG. 3, at least a portion of the first electrode 11 is porous. With this configuration, the first electrode 11 is likely to have a large surface area, which makes it more likely that the capacitor 1c has a high capacitance. Such a porous structure can be formed by any of the processes including, for example, etching of metal foil and powder sintering processes.

As illustrated in FIG. 3, the film of the dielectric material 20 is disposed, for example, on an upper part of the porous portions of the first electrode 11. Examples of processes for forming the dielectric material 20 that can be employed include spin coating, ink jetting, die coating, roll coating, bar coating, Langmuir-Blodgett technique, dip coating, and spray coating. In the capacitor 1c, the dielectric material 20 is disposed, for example, to fill a space around the porous portions of the first electrode 11.

FIG. 4 is a cross-sectional view illustrating still another exemplary capacitor of the present disclosure. In a capacitor 1d, illustrated in FIG. 4, the dielectric material 20 is in the form of, for example, a film. In this film, a different dielectric material 22 which is different from the dielectric material 20 is disposed in a dispersed manner. A process that can be employed to form the film is spin coating, ink jetting, die coating, roll coating, bar coating, Langmuir-Blodgett technique, dip coating, or spray coating. The film including the dielectric material 20 and the different dielectric material 22 can be obtained, for example, by forming, with any of the above-mentioned processes, a coating of a precursor liquid containing the raw material of the dielectric material 20 and particles of the different dielectric material 22. The film may be formed by sputtering, anodizing, vacuum vapor deposition, PLD, ALD, or CVD.

The different dielectric material 22 is not limited to any particular dielectric material as long as it is a type of dielectric material different from the dielectric material 20. The different dielectric material 22 has, for example, a higher relative dielectric constant than the dielectric material 20. The different dielectric material 22 may be, for example, a perovskite compound, for example, such as BaTiO₃, PbTiO₃, or SrTiO₃. The different dielectric material 22 may be a layered perovskite compound. The different dielectric material 22 may include at least one selected from the group consisting of Ruddlesden-Popper compounds, Dion-Jacobson compounds, tungsten bronze compounds, and pyrochlore compounds.

The size of the particles of the different dielectric material 22 is not limited to a particular value. The particles of the different dielectric material 22 have a size of, for example, greater than or equal to 1 nm and less than or equal to 100 nm.

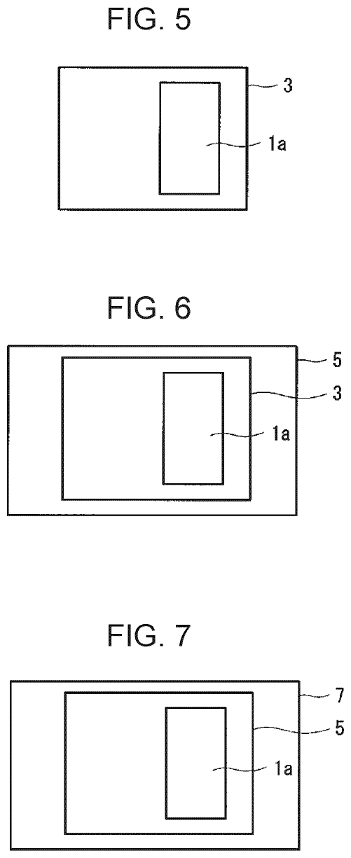

FIG. 5 is a schematic diagram illustrating an exemplary electrical circuit of the present disclosure. An electrical circuit 3 includes the capacitor 1a. The electrical circuit 3 may be an active circuit or a passive circuit. The electrical circuit 3 may be a discharge circuit, a smoothing circuit, a decoupling circuit, or a coupling circuit. Since the electrical circuit 3 comprises the capacitor 1a, the electrical circuit 3 easily exhibits desired properties. For example, the capacitor 1a facilitates reducing noise in the electrical circuit 3. The electrical circuit 3 may include the capacitor 1b, the capacitor 1c, or the capacitor 1d in place of the capacitor 1a.

FIG. 6 is a schematic diagram illustrating an exemplary circuit board of the present disclosure. As illustrated in FIG. 6, a circuit board 5 includes the capacitor 1a. For example, the electrical circuit 3 including the capacitor 1a is formed on the circuit board 5. The circuit board 5 may be an embedded board or a motherboard. The circuit board 5 may include the capacitor 1b, the capacitor 1c, or the capacitor 1d in place of the capacitor 1a.

FIG. 7 is a schematic diagram illustrating an exemplary device of the present disclosure. As illustrated in FIG. 7, a device 7 includes, for example, the capacitor 1a. The device 7 includes, for example, the circuit board 5 including the capacitor 1a. Since the device 7 comprises the capacitor 1a, the device 7 easily exhibits desired properties. The device 7 may be an electronic device, a communication device, a signal processing device, or a power supply device. The device 7 may be a server, an AC adapter, an accelerator, or a flat panel display, such as a liquid crystal display device (LCD). The device 7 may be a USB charger, a solid stated drive (SSD), an information terminal, such as a PC, a smartphone, or a tablet PC, or an ethernet switch.

### Supplementary Notes

According to what has been described above, the following technologies are disclosed.

(Technology 1) A capacitor comprising:
a first electrode;
a second electrode; and
a dielectric material disposed between the first electrode and the second electrode, the dielectric material comprising a composite oxide, wherein
the composite oxide is composed of:
   O,
   at least one selected from the group consisting of K, Rb, and Cs,
   at least one selected from the group consisting of Si, Ge, and Sn, and
   at least one selected from the group consisting of Mo and W.

(Technology 2) The capacitor according to Technology 1, wherein the composite oxide comprises one of K, Rb, and Cs.

(Technology 3) The capacitor according to Technology 1, wherein the composite oxide comprises one of Cs and K.

(Technology 4) The capacitor according to any one of Technologies 1 to 3, wherein the composite oxide comprises one of Si, Ge, and Sn.

(Technology 5) The capacitor according to any one of Technologies 1 to 4, wherein the composite oxide comprises one of Mo and W.

(Technology 6) The capacitor according to any one of Technologies 1 to 5, wherein the composite oxide has a composition represented by A_{α}B_{β}C_{γ}O_{≢7}, where
A is at least one selected from the group consisting of K, Rb, and Cs,
B is at least one selected from the group consisting of Si, Ge, and Sn,
C is at least one selected from the group consisting of Mo and W,

$$\begin{matrix}0.9 \leq α \leq 1 \text{.1} , \\ 0.25 \leq β \leq 1 , \\ 1 \leq γ \leq 2 , and \\ 5.5 \leq δ \leq 6.5 .\end{matrix}$$

(Technology 7) The capacitor according to any one of Technologies 1 to 6, wherein the composite oxide has a pyrochlore-type crystal structure.

(Technology 8) A dielectric material for a capacitor, the dielectric material comprising a composite oxide composed of:
O;
at least one selected from the group consisting of K, Rb, and Cs;
at least one selected from the group consisting of Si, Ge, and Sn; and
at least one selected from the group consisting of Mo and W.

(Technology 9) An electrical circuit comprising the capacitor according to any one of Technologies 1 to 7.

(Technology 10) A circuit board comprising the capacitor according to any one of Technologies 1 to 7.

(Technology 11) A device comprising the capacitor according to any one of Technologies 1 to 7.

### EXAMPLES

Hereinafter, the present disclosure will now be described in detail with reference to Examples. The Examples described below are merely illustrative, and the present disclosure is not limited to the Examples described below.

### Calculation of Relative Dielectric Constant

The structure of a crystal having a composition of RbTi_{0.5}W_{1.5}O₆ (mp-1219784) was retrieved from the Materials Project database (https://materialsproject.org/). For composite oxides that were the targets of the calculation, which had predetermined compositions, their initial structure was determined by replacing some elements in the structure of RbTi_{0.5}W_{1.5}O₆. Structural optimization calculation using a density functional theory method (DFT method), which is a first-principles calculation method, was then performed on the determined initial structure. This calculation was carried out with the Vienna Ab initio Simulation Package (VASP) code. Phonon calculation was then performed on a stable structure determined by the structural optimization calculation; the phonon calculation used a first-principles perturbation calculation method (DFPT method). The DFPT method is a method that, in order to quantify the dielectric constant of a single-crystal dielectric material, provides an electric field as a perturbation to the crystal and calculates changes in polarization, as described in the literature mentioned below. The results of the phonon calculation were parsed with a python package pymatgen to calculate a relative dielectric constant εᵣ of the composite oxides. In addition, a bandgap E_{g} was also calculated. The results are shown in Table 3.

Stefano Baroni et al., “Phonons and related crystal properties from density-functional perturbation theory”, Reviews of Modern Physics, Volume 73, 2001

The validity of the above-described calculation of the relative dielectric constant was verified as follows. The relative dielectric constant at −273° C. of BaTa₂O₆, which is described by NPL 1, and BaNb₂O₆, which is described by NPL 2, was calculated in accordance with the above-described manner of calculation. The calculated values of the relative dielectric constant were compared with the measured values described by NPL 1 and NPL 2. The results are shown in Table 2. As shown in Table 2, the calculated values can be considered to be equivalent to the measured values. Accordingly, the present inventors believe that the above-described calculation is valid and that the calculated values of the relative dielectric constant provided by the above-described calculation are equivalent to the measured values.

TABLE 2

| | | Relative |
|---|---|---|
| | | Dielectric |
| Composition | Class of Values | Constant |
| BaTa₂O₆ | Measured value | 50 |
| BaTa₂O₆ | Calculated value | 49 |
| BaNb₂O₆ | Measured value | 47 |
| BaNb₂O₆ | Calculated value | 52 |

### Evaluation of Dielectric Breakdown Field

A dielectric breakdown field E at −273° C. of the composite oxides was calculated based on the bandgap E_{g} obtained from the first-principles calculation. The dielectric breakdown field E was calculated according to equation (1a) and equation (1b) shown below, with reference to Wang, Li-Mo. “Relationship between Intrinsic Breakdown Field and Bandgap of Materials.”, 2006 25th International Conference on Microelectronics. IEEE, 2006. In the equations below, the units of E and E_{g} were V/nm and eV, respectively. The calculation results are shown in Table 3.

$$E = 1.36 \times {( {E}_{g} / 4 )}^{3} ( if {E}_{g} < 4 ) \qquad equation ( 1 a )$$

$$E = 1.36 \times ( {E}_{g} / 4 ) ( if {E}_{g} \geq 4 ) \qquad equation ( 1 b )$$

### Evaluation of Energy Density

A calculated value of an energy density W of the composite oxides was obtained according to equation (2) shown below, based on the relative dielectric constant Er and the dielectric breakdown field E [V/nm] of the composite oxides, which were calculated as described above. In equation (2), ε₀ is the dielectric constant of a vacuum, and the unit of the energy density W is [Wh/liter (L)]. The results are shown in Table 3.

$$W = ( 1 / 7.2 ) \times 1 {0}^{12} \cdot {ε}_{0} \cdot {ε}_{r} \cdot {( E )}^{2} \qquad equation ( 2 )$$

### REFERENCE EXAMPLE

A raw material powder (3 grams) was prepared. The raw material powder contained Cs₂Co₃, TiO₂, and WO₃ so as to satisfy a condition of molar amount of Cs₂Co₃: molar amount of TiO₂: molar amount of WO₃=1:1:3. The raw material powder was ground and mixed in a mortar. The mixed powder obtained in this manner was placed in a pressure molding die assembly and pressed at a pressure of 20 MPa to form a pellet. The obtained pellet was sintered in air at 850° C. for 80 hours. The sintered pellet was ground again in the mortar to provide a powdered composite oxide of a Reference Example. The composite oxide of the Reference Example had a composition represented by

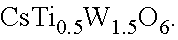

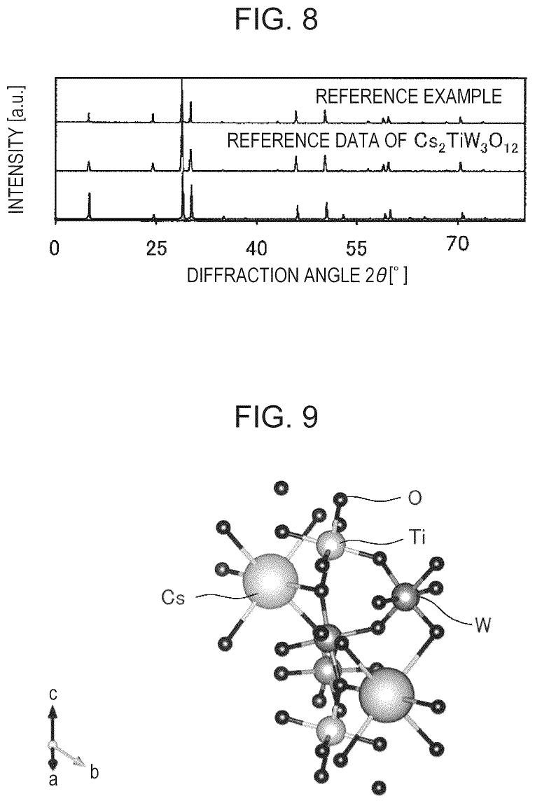

An X-ray diffraction (XRD) measurement was performed on the composite oxide of the Reference Example to determine its crystal structure. The X-ray used in this measurement was Cu-Kα radiation, and the measurement was performed under a dry argon atmosphere. FIG. 8 is a graph showing an XRD pattern of the composite oxide of the Reference Example. In the graph, the horizontal axis represents a diffraction angle 2θ, and the vertical axis represents an intensity of X-ray diffraction. FIG. 8 shows reference data of an X-ray diffraction pattern of Cs₂TiW₃O₁₂. The reference data was retrieved from the Inorganic Crystal Structure Database (ICSD). The XRD pattern of the composite oxide of the Reference Example matched the reference data of the X-ray diffraction pattern of Cs₂TiW₃O₁₂ retrieved from the ICSD. This suggested that the composite oxide of the Reference Example had a pyrochlore-type crystal structure.

Structural optimization calculation was performed on the composite oxide having the composition of CsTi_{0.5}W_{1.5}O₆, according to the first-principles calculation method described above in the Calculation of Relative Dielectric Constant section. FIG. 9 is a diagram illustrating a stable structure of CsTi_{0.5}W_{1.5}O₆. FIG. 9 suggests that the composite oxide having the composition of CsTi_{0.5}W_{1.5}O₆ has a pyrochlore-type crystal structure.

Structural optimization calculation was performed on composite oxides having the following compositions, by the first-principles calculation method described above in the Calculation of Relative Dielectric Constant section.

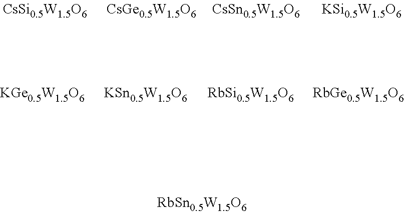

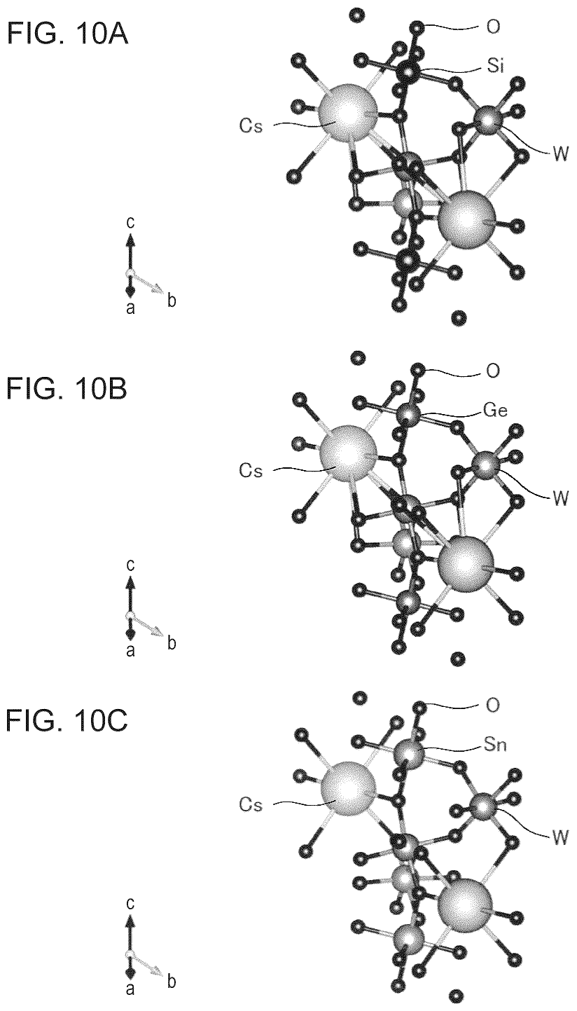

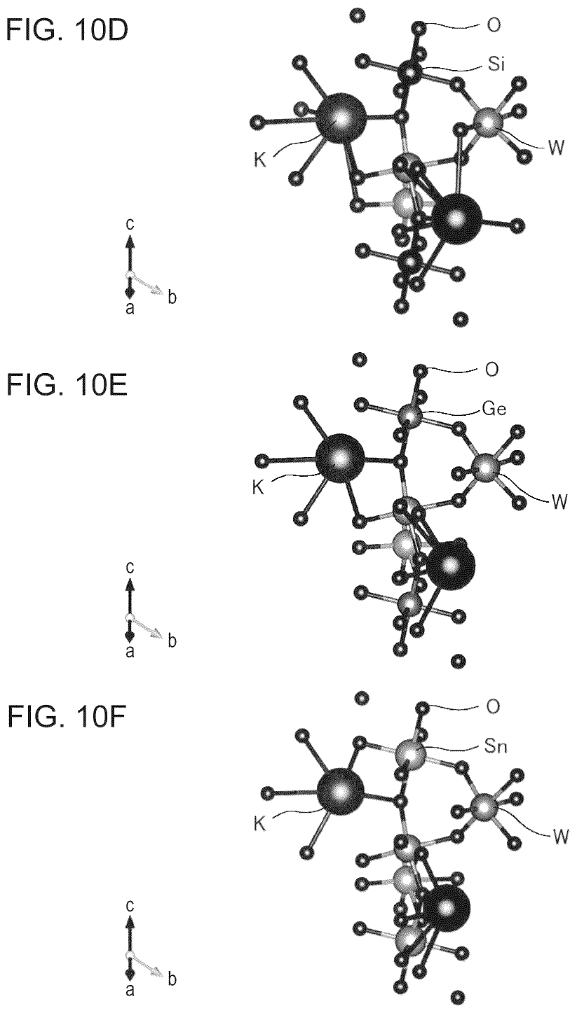

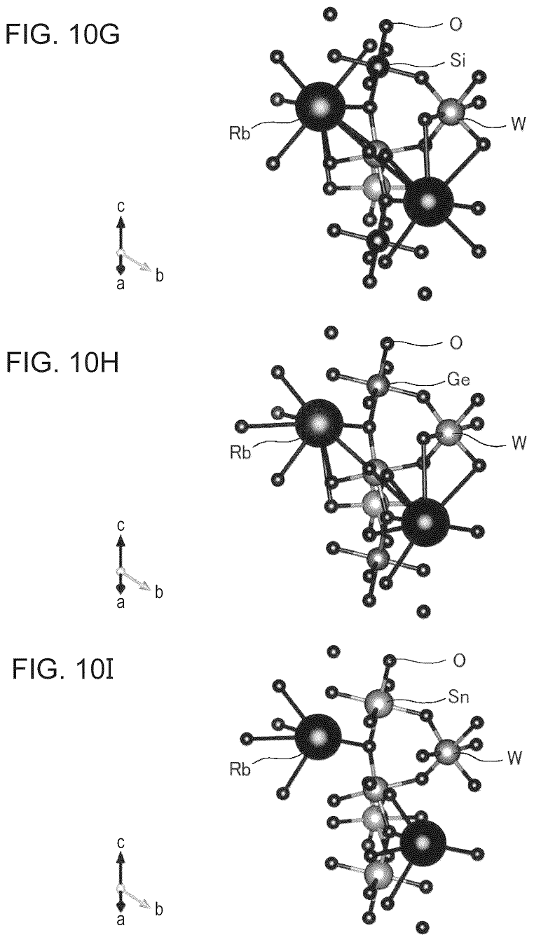

FIG. 10A is a diagram illustrating a stable structure of CsSi_{0.5}W_{1.5}O₆. FIG. 10B is a diagram illustrating a stable structure of CsGe_{0.5}W_{1.5}O₆. FIG. 10C is a diagram illustrating a stable structure of CsSn_{0.5}W_{1.5}O₆. FIG. 10D is a diagram illustrating a stable structure of KSi_{0.5}W_{1.5}O₆. FIG. 10E is a diagram illustrating a stable structure of KGe_{0.5}W_{1.5}O₆. FIG. 10F is a diagram illustrating a stable structure of KSn_{0.5}W_{1.5}O₆. FIG. 10G is a diagram illustrating a stable structure of RbSi_{0.5}W_{1.5}O₆. FIG. 10H is a diagram illustrating a stable structure of RbGe_{0.5}W_{1.5}O₆. FIG. 10I is a diagram illustrating a stable structure of RbSn_{0.5}W_{1.5}O₆. A comparison of FIGS. 10A to 10I with FIG. 9 suggested that CsSi_{0.5}W_{1.5}O₆, CsGe_{0.5}W_{1.5}O₆, CsSn_{0.5}W_{1.5}O₆, KSi_{0.5}W_{1.5}O₆, KGe_{0.5}W_{1.5}O₆, KSn_{0.5}W_{1.5}O₆, RbSi_{0.5}W_{1.5}O₆, RbGe_{0.5}W_{1.5}O₆, and RbSn_{0.5}W_{1.5}O₆ had a pyrochlore-type crystal structure.

As shown in Table 3, it was suggested that composite oxides comprising at least one selected from the group consisting of K, Rb, and Cs, at least one selected from the group consisting of Si, Ge, and Sn, and at least one selected from the group consisting of Mo and W have a higher relative dielectric constant than BaTa₂O₆ and than BaNb₂O₆. In addition, it was suggested that these composite oxides have a high dielectric breakdown field. In addition, it was suggested that these composite oxides have a high energy density. It is seen that capacitors including a dielectric material containing such a composite oxide are advantageous in terms of the capacitance and the dielectric breakdown field.

TABLE 3

| | | | Dielectric | |
|---|---|---|---|---|
| | Relative | | Breakdown | |
| | Dielectric | | Field E | |
| | Constant εᵣ | Bandgap E_{g} | (calculated | Energy |
| | (calculated | (calculated | value) | Density |
| Composition | value) | value) [eV] | [V/nm] | [Wh/L] |
| CsGe_{0.5}W_{1.5}O₆ | 253 | 4.27 | 14.52 | 656 |
| CsSi_{0.5}W_{1.5}O₆ | 185 | 4.10 | 13.94 | 441 |
| CsSn_{0.5}W_{1.5}O₆ | 57 | 4.63 | 15.74 | 174 |
| KGe_{0.5}Mo_{1.5}O₆ | 317 | 3.96 | 13.20 | 679 |
| KGe_{0.5}W_{1.5}O₆ | 189 | 4.66 | 15.84 | 583 |
| RbGe_{0.5}W_{1.5}O₆ | 98 | 4.45 | 15.13 | 276 |
| RbSi_{0.5}W_{1.5}O₆ | 194 | 4.17 | 14.18 | 480 |
| RbSn_{0.5}W_{1.5}O₆ | 63 | 4.77 | 16.22 | 204 |
| BaTa₂O₆ | 49 | 3.74 | 11.11 | 134 |
| BaNb₂O₆ | 52 | 3.92 | 12.81 | 103 |

The capacitors of the present disclosure are useful in terms of the capacitance and the dielectric breakdown field.

What is claimed is:

1. A capacitor comprising:
a first electrode;
a second electrode; and
a dielectric material disposed between the first electrode and the second electrode, the dielectric material comprising a composite oxide,
wherein
the composite oxide is composed of:
O,
at least one selected from the group consisting of K, Rb, and Cs,
at least one selected from the group consisting of Si, Ge, and Sn, and
at least one selected from the group consisting of Mo and W.

2. The capacitor according to claim 1, wherein
the composite oxide comprises one of K, Rb, and Cs.

3. The capacitor according to claim 2, wherein
the composite oxide comprises one of Cs and K.

4. The capacitor according to claim 1, wherein
the composite oxide comprises one of Si, Ge, and Sn.

5. The capacitor according to claim 1, wherein
the composite oxide comprises one of Mo and W.

6. The capacitor according to claim 1, wherein the composite oxide has a composition represented by A_{α}B_{γ}C_{γ}O_{δ}, where
A is at least one selected from the group consisting of K, Rb, and Cs,
B is at least one selected from the group consisting of Si, Ge, and Sn,
C is at least one selected from the group consisting of Mo and W,
$$\begin{matrix}0.9 \leq α \leq 1.1 , \\ 0.25 \leq β \leq 1 , \\ 1 \leq γ \leq 2 , and \\ 5.5 \leq δ \leq 6.5 .\end{matrix}$$

7. The capacitor according to claim 1, wherein
the composite oxide has a pyrochlore crystal structure.

8. A dielectric material for a capacitor, the dielectric material comprising a composite oxide composed of:
O;
at least one selected from the group consisting of K, Rb, and Cs;
at least one selected from the group consisting of Si, Ge, and Sn; and
at least one selected from the group consisting of Mo and W.

9. An electrical circuit comprising the capacitor according to claim 1.

10. A circuit board comprising the capacitor according to claim 1.

11. A device comprising the capacitor according to claim 1.
